(19) United States
(12) Patent Application Publication
(10) Pub. No.: US 2026/0215288 A1
(43) Pub. Date: Jul. 23, 2026

(54) SEMICONDUCTOR STRUCTURE AND PACKAGE STRUCTURE

(71) Applicant: ENNOSTAR CORPORATION, Hsinchu City (TW)

(72) Inventors: CHANG-TAI HSIAO, Hsinchu City (TW); CHENG-WEI PENG, Hsinchu City (TW)

(21) Appl. No.: 19/456,393

(22) Filed: Jan. 22, 2026

(30) Foreign Application Priority Data
Jan. 23, 2025 (TW) 114102986

(51) Int. Cl. H10W 46/00; H10H 20/819; H10W 74/10

(52) U.S. Cl. CPC H10W 46/301; H10H 20/819; H10W 46/601; H10W 74/124

(57) ABSTRACT

A semiconductor structure includes a first surface, a second surface, a semiconductor portion, and a first penetrating portion. The second surface is opposite to the first surface. The first penetrating portion penetrates the semiconductor portion. The first penetrating portion has a first opening located on the first surface and a second opening located on the second surface. The first penetrating portion allows an ambient medium to penetrate the semiconductor portion through the first opening and the second opening.

### TECHNICAL FIELD

The present disclosure relates to a semiconductor structure, and particularly relates to a semiconductor structure and a package structure for mass transfer technique.

### CROSS REFERENCE TO RELATED APPLICATION

This application claims the right of priority based on TW Application Serial No. 114102986, filed on Jan. 23, 2025, and the content of which is hereby incorporated by reference in its entirety.

### Description of Background Art

Light-emitting diodes (LEDs) are optoelectronic semiconductor devices having low power consumption, low heat generation, long service life, shock resistance, compact size, and fast response. Therefore, LEDs are suitable for various lighting and display applications. As semiconductor fabrication processes continue to develop, the size of LED chips has gradually shrunk to below 100 μm, 50 μm, or 30 μm, and the number of chips producible per unit area has correspondingly increased. In manufacturing processes that incorporate LED chips into products, lasers are commonly used to transfer millions of LED chips from an original substrate to a target substrate. When irradiated with a laser, the LED chips detach from the original substrate and fall onto the target substrate. However, the precision of chip transfer in such transfer techniques still requires improvement.

### SUMMARY OF THE DISCLOSURE

The present disclosure provides a semiconductor structure and a package structure for mass transfer techniques to improve the precision of chip transfer.

In some embodiments, the semiconductor structure includes a first surface, a second surface, a semiconductor portion, and a first penetrating portion. The second surface is opposite to the first surface. The first penetrating portion penetrates the semiconductor portion. The penetrating portion is communicated with an ambient medium.

In some embodiments, the package structure includes a bearing substrate, a semiconductor device, a package layer and a penetrating portion. The semiconductor device is disposed on the bearing substrate. The package layer covers the semiconductor device and the bearing substrate. The penetrating portion penetrates the package layer and is communicated with an ambient medium.

### BRIEF DESCRIPTION OF THE DRAWINGS

FIG. 1A shows a schematic diagram of a plurality of semiconductor structures at different transfer steps according to some embodiments of the present disclosure.

FIG. 1B shows a schematic top view of a plurality of semiconductor structures according to some embodiments of the present disclosure.

FIG. 2 shows a schematic top view of a plurality of semiconductor devices according to some embodiments of the present disclosure.

FIG. 3 shows a schematic cross-sectional view taken along line E-E in FIG. 2.

FIG. 4 shows a schematic diagram of a semiconductor structure during a transfer process according to some embodiments of the present disclosure.

FIG. 5 shows a schematic top view of a plurality of package structures according to some embodiments of the present disclosure.

FIG. 6 shows a schematic cross-sectional view taken along line F-F in FIG. 5.

FIG. 7 shows a schematic top view of a plurality of alignment keys according to some embodiments of the present disclosure.

FIG. 8(a) shows a schematic cross-sectional view taken along line A-A in FIG. 7, and FIG. 8(b) shows a schematic cross-sectional view taken along line B-B in FIG. 7.

FIG. 9 shows a schematic top view of a semiconductor structure according to some embodiments of the present disclosure.

FIG. 10 shows a schematic sectional view of a plurality of semiconductor structures according to some embodiments of the present disclosure.

### DETAILED DESCRIPTION OF PREFERRED EMBODIMENTS

With respect to spatially relative terms referenced in the present disclosure, such as “upper” and “lower”, these terms are used for convenience to describe the relative relationship of one element or feature to another (or others) as illustrated in the drawings. In addition to the orientations depicted in the drawings, these spatially relative terms are also used to describe the orientation of the elements during use and operation. As the orientation of the element's changes (e.g., rotated 90 degrees or to other orientations), the corresponding descriptive terminology regarding orientation is to be interpreted accordingly.

In addition, terms “first”, “second”, “third” are used to describe elements, components, regions, layers, and/or sections in the present disclosure. However, such terms are not intended to limit elements, components, regions, layers, and/or sections. The terms are merely used to distinguish one element, component, region, layer, and/or section from another and do not imply any priority, sequence, or ordinal numbering. Therefore, without departing from the scope of the embodiments of the present disclosure, a “first” element, component, region, layer, or section discussed below may be referred to as a “second” element, component, region, layer, or section.

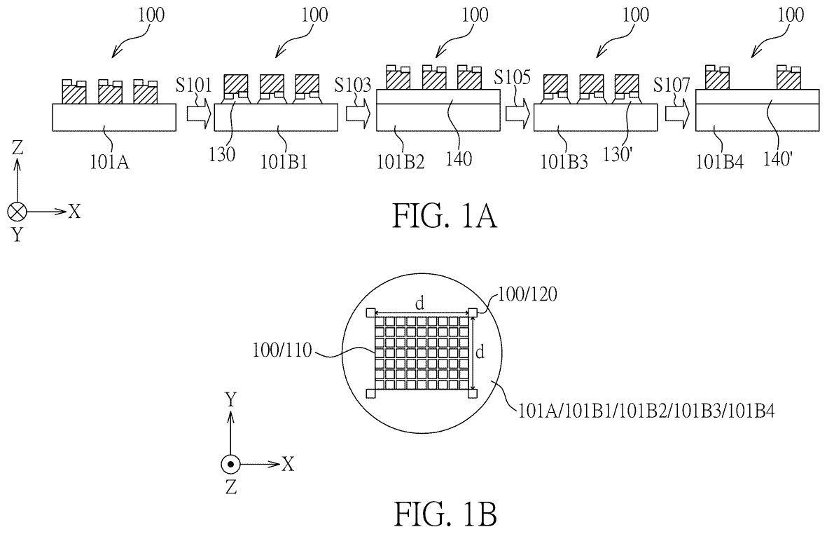

FIG. 1A shows a schematic diagram of a plurality of semiconductor structures 100 at different transfer steps S101, S103, S105, S107, and FIG. 1B shows a schematic top view of the plurality of semiconductor structures 100. Adhesive layers 130, 130′, 140, 140′ are not shown in FIG. 1B. The plurality of semiconductor structures 100 include semiconductor devices 110 and/or alignment keys 120. In some embodiments, each semiconductor device 110 includes an LED chip, and each alignment key 120 includes a key chip. The plurality of semiconductor devices 110 are arranged in an array on a growth substrate 101A or transfer carriers 101B1, 101B2, 101B3, 101B4. The alignment keys 120 are located at an outer periphery of the semiconductor devices 110, and two adjacent alignment keys 120 are spaced by at least a distance d. In some embodiments, the growth substrate 101A may be a silicon substrate or a sapphire substrate, and each of the transfer carriers 101B1, 101B2, 101B3, 101B4 may be a silicon substrate, a sapphire substrate, or a glass substrate.

First, as shown in FIG. 1A, the plurality of semiconductor structures 100 is provided and formed on the growth substrate 101A. The plurality of semiconductor structures 100 includes semiconductor devices 110 and/or alignment keys 120 shown in FIG. 1B. The plurality of semiconductor structures 100 is transferred form the growth substrate 101A to the adhesive layer 130 of the transfer carrier 101B1 through the transfer step S101. Next, the plurality of semiconductor structures 100 is transferred from the adhesive layer 130 of the transfer carrier 101B1 to the adhesive layer 140 of the transfer carrier 101B2 through the transfer step S103. Optionally, by further performing the transfer steps S105, S107, the plurality of semiconductor structures 100 detaches from the adhesive layer 140 of the transfer carrier 101B2 and the adhesive layer 130′ of the transfer carrier 101B3 in a sequence to be transferred to the adhesive layer 140′ of the transfer carrier 101B4. In some embodiments, the transfer steps S101, S103, S105, S107 include bonding process, peeling-off process, laser lift-off (LLO) process, and/or laser de-bonding (LDB) process. In some embodiments, at least one of the adhesive layers 130, 130′, 140, 140′ includes a laser de-bonding film or a silicone tape. In some embodiments, at least one of the adhesive layers 130, 130′, 140, 140′ includes epoxy or polyimide (PI). In some embodiments, the adhesive layers 130, 130′ are provides in a one-to-one correspondence with the plurality of semiconductor structures 100, and the adhesive layers 140, 140′ are continuous layers connecting the plurality of semiconductor structures 100. In other embodiments, at least one of the adhesive layers 140, 140′ is provided in a one-to-one correspondence with the plurality of semiconductor structures 100 (not shown). In other embodiments, at least one of the adhesive layers 130, 130′ is a continuous layer connecting the plurality of semiconductor structures 100 (not shown).

In the transfer steps S101, S103, S105, S107, the plurality of semiconductor structures 100 is transferred from a donor substrate to an acceptor substrate. In at least one of the transfer steps S101, S103, S105, S107, the plurality of semiconductor structures 100 detaches from the donor substrate and falls onto the acceptor substrate. In some embodiments, in the transfer steps S101, S103, S105, S107, sorting process and/or mixing process for the plurality of semiconductor structures 100 can be simultaneously performed according to features of the plurality of semiconductor structures 100. The features of the plurality of semiconductor structures 100 include shapes, optical characteristics, or electrical characteristics. In some embodiments, in the transfer steps S101, S103, S105, S107, a distance between two adjacent semiconductor structures 100 is adjusted. In some embodiments, each of the plurality of semiconductor structures 100 on the growth substrate 101A includes electrodes away from the growth substrate 101A, and the electrodes are located within the adhesive layers 130, 130′ or exposed outside the adhesive layers 140, 140′ by following the transfer steps S101, S103, S105, S107. In other words, the plurality of semiconductor structures 100 exposes different surfaces after different transfer steps.

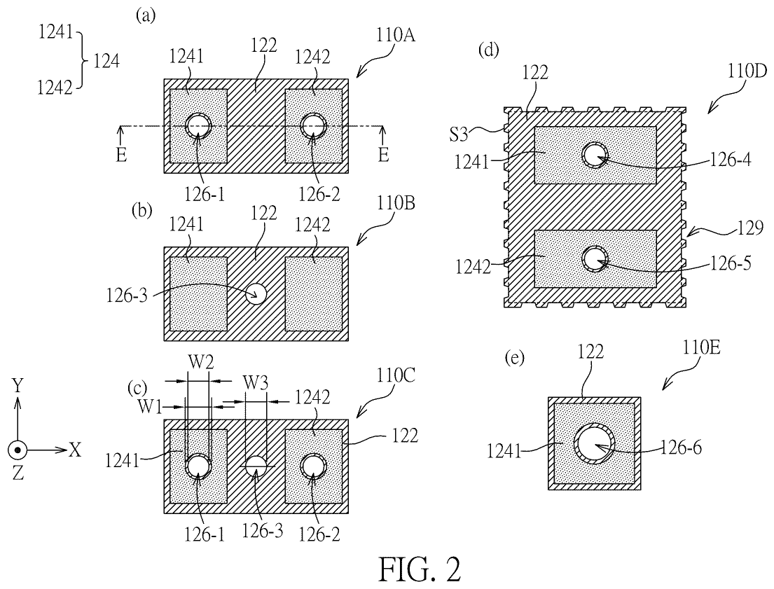

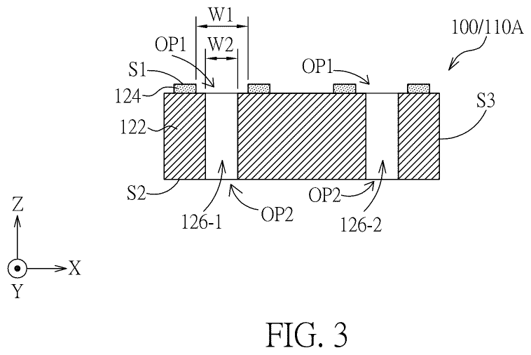

FIG. 2 shows a schematic top view of semiconductor devices 110A, 110B, 110C, 110D, 110E according to some embodiments of the present disclosure, and FIG. 3 shows a schematic cross-sectional view taken along line E-E in FIG. 2. In some embodiments, the semiconductor devices 110A, 110B, 110C, 110D may be LED chips having a lateral structure, and the semiconductor device 110E may be an LED chip having a vertical structure. As shown in FIG. 2 and FIG. 3, the semiconductor device 110A includes a semiconductor portion 122, a metal portion 124 and one or more penetrating portions. The semiconductor portion 122 includes an epitaxial stack including III-V compound semiconductor layers, and the epitaxial stack includes a p-type semiconductor layer, an active layer, and an n-type semiconductor layer (not shown). The metal portion 124 include two electrodes 1241, 1242 and respectively electrically connected to the p-type semiconductor layer and the n-type semiconductor layer (or n-type semiconductor layer and the p-type semiconductor layer).

As shown in FIG. 2(a) and FIG. 3, the two electrodes 1241, 1242 are located on a same side of the semiconductor portion 122 which is defined as the lateral structure The semiconductor device 110A has penetrating portions 126-1, 126-2. The penetrating portions 126-1, 126-2 are respectively located on the two electrodes 1241, 1242 of the metal portion 124 and penetrate the semiconductor portion 122 and the two electrodes 1241, 1242 of the metal portion 124.

As shown in FIG. 3, in some embodiments, the semiconductor device 110A includes a first surface S1, a second surface S2, and a third surface S3. The second surface S2 is opposite to the first surface S1, and the third surface S3 is located between the first surface S1 and the second surface S2. The first surface S1 includes an upper surface of the metal portion 124, the second surface S2 includes a lower surface of the semiconductor portion 122, and the third surface S3 includes a side surface of the semiconductor portion 122. Each of the penetrating portion 126-1 and the penetrating portion 126-2 has a first opening OP1 located at the first surface S1 and a second opening OP2 located at the second surface S2. In some embodiments, the penetrating portions 126-1, 126-2 are communicated with an ambient medium, such as air. Specifically, the penetrating portions 126-1, 126-2 allow the ambient medium to flow through the semiconductor device 110A via the first opening OP1 of the first surface S1 and the second opening OP2 of the second surface S2. In other words, the penetrating portion 126-1 and the penetrating portion 126-2 are not completely filled with other material (such as metal). In some embodiments, widths W1 of the penetrating portion 126-1 and the penetrating portion 126-2 in the metal portion 124 are greater than their widths W2 in the semiconductor portion 122 (as shown in FIG. 3). In other embodiments, the widths W1 of the penetrating portion 126-1 and the penetrating portion 126-2 in the metal portion 124 are the same as their widths W2 in the semiconductor portion 122 (not shown).

As shown in FIG. 2(b), the semiconductor device 110B further includes a penetrating portion 126-3. The penetrating portion 126-3 penetrates the semiconductor portion 122 but does not penetrate the metal portion 124. In some embodiments, the penetrating portion 126-3 has the first opening OP1 and the second opening OP2. In some embodiments, the penetrating portion 126-3 of the semiconductor device 110B is located between the two electrodes 1241, 1242 of the semiconductor device 110B.

As shown in FIG. 2(c), the semiconductor device 110C includes the penetrating portions 126-1, 126-2, 126-3. The penetrating portion 126-3 penetrates the semiconductor portion 122 but does not penetrate the metal portion 124. In some embodiments, the penetrating portion 126-3 is located between the penetrating portions 126-1, 126-2. In some embodiments, a width W3 of the third penetrating portion 126-3 is less than a width W1, W2 of the penetrating portion 126-1.

As shown in FIG. 2(d), the semiconductor device 110D includes penetrating portions 126-4, 126-5, and a concave-convex structure 129. The concave-convex structure 129 is located on the third surface S3, and the concave-convex structure 129 allows an ambient medium to flow through during a transfer process of the semiconductor device 110D. In some embodiments, the third surface S3 is a side surface of the semiconductor portion 122.

As shown in FIG. 2(e), the two electrodes 1241, 1242 (the electrode 1242 is not shown) of the semiconductor device 110E are disposed on opposite sides of the semiconductor portion 122, which is defined as the vertical structure. The penetrating portion 126-6 penetrates the semiconductor portion 122, the metal portion 124, and the penetrating portion 126-6 has a first opening OP1 and a second opening OP2 at the first surface S1 and the second surface S2 (referring to FIG. 3) of the semiconductor device 110E. The penetrating portion 126 allows an ambient medium to flow through the semiconductor device 110E via the first opening OP1 and the second opening OP2.

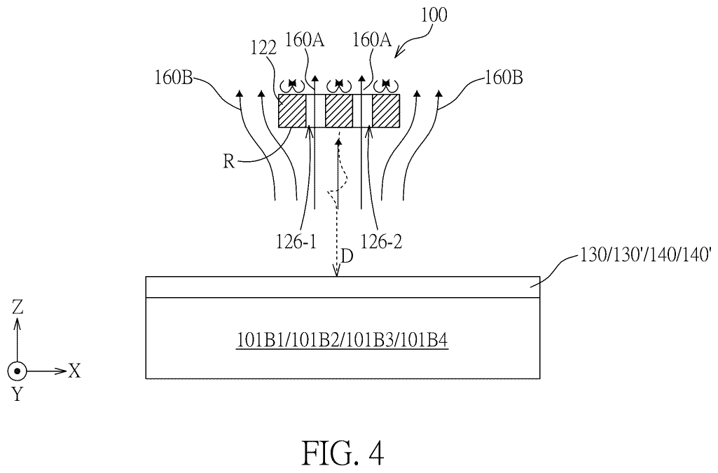

FIG. 4 shows a schematic diagram of the semiconductor structure 100 during a transfer process according to some embodiments of the present disclosure, and the semiconductor structure 100 is illustrated with reference to the semiconductor device 110A shown in FIG. 3. As shown in FIG. 4, in some embodiments, the semiconductor structure 100 drops along a direction of a dashed arrow D and is transferred to the transfer carrier 101B1, 101B2, 101B3, 101B4 during the transfer steps S101, S103, S105, S107. When the semiconductor structure 100 is dropping, the ambient medium may generate airflow to disturb the movement of the semiconductor structure 100 and the first surface S1 or the second surface S2 of the semiconductor structure 100 facing the transfer carrier 101B1, 101B2, 101B3, 101B4 is defined as a resistance surface R with respect to the ambient medium (air) to generate a resistance force (fluid resistance).

In some embodiments, when the semiconductor structure 100 is dropping, the ambient medium may generate a bypass airflow 160B around a periphery of the semiconductor structure 100 and a core airflow 160A passing through the penetrating portions 126-1, 126-2 of the semiconductor structure 100, which results in that the resistance force generated by the resistance surface R (e.g., the first surface S1 of the semiconductor structure 100 or the second surface S2 of the semiconductor structure 100) can be reduced. Therefore, the semiconductor structure 100 can be stably transferred to the adhesive layers 130, 130′, 140, 140′ of the transfer carriers 101B1, 101B2, 101B3, 101B4.

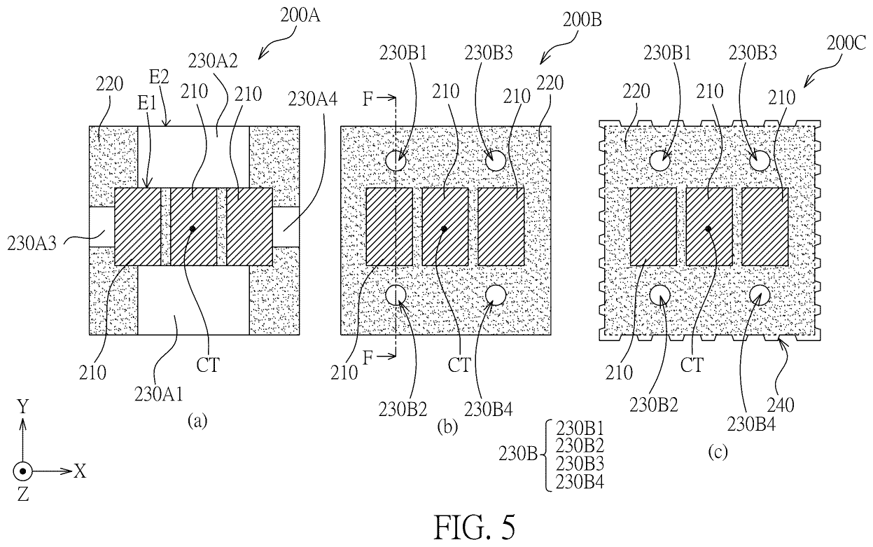

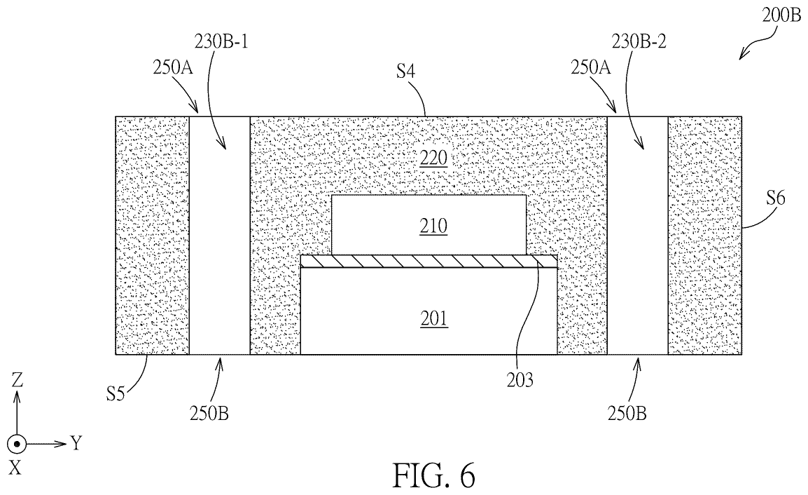

FIG. 5 shows a schematic top view of package structures according to some embodiments of the present disclosure, and FIG. 6 shows a schematic cross-sectional view taken along line F-F in FIG. 5. Referring to FIG. 5 and FIG. 6, the present disclosure provides package structures 200A, 200B, 200C. Each of the package structures 200A, 200B, 200C includes a bearing substrate 201, a semiconductor device 210, a package layer 220, and penetrating portions 230A1-230A4, 230B1-230B4. The semiconductor device 210 is disposed on the bearing substrate 201. The bearing substrate 201 may be a silicon substrate, a sapphire substrate, or a glass substrate. The package layer 220 covers the semiconductor device 210 and the bearing substrate 201. The package layer 220 includes resin materials (e.g., epoxy resin or silicone), and the package layer 220 may be a single-layer structure or a multi-layer structure. In some embodiments, a plurality of semiconductor devices 210 is disposed on the bearing substrate 201 and the package layer 220 cover the plurality of semiconductor devices 210.

In some embodiments, the plurality of semiconductor devices 210 can emit different light. For example, the plurality of semiconductor devices 210 includes an LED or laser chip emitting red light, an LED or laser chip emitting green light, and an LED or laser chip emitting blue light. The package layer 220 includes a first surface S4, a second surface S5, and a third surface S6. The second surface S5 is opposite to the first surface S4, and the third surface S6 is located between the first surface S4 and the second surface S5.

As shown in FIG. 5, the penetrating portions 230A1-230A4, 230B1-230B4 are symmetrically arranged with respect to a center point CT of the package structures 200A, 200B, 200C (e.g., rotational symmetry or mirror symmetry), and the penetrating portions 230A1-230A4, 230B1-230B4 and the semiconductor device 210 are not overlapped with each other in a vertical projection (i.e., a top view direction).

As shown in FIG. 5(a), one or more of the penetrating portions 230A1, 230A2, 230A3, 230A4 of the package structure 200A extend from an edge side of the semiconductor device 210 to an edge of the package layer 220. For example, the penetrating portions 230A2 extend from an edge side E1 of the semiconductor device 210 to an edge E2 of the package layer 220. The penetrating portions 230A1, 230A2, 230A3, 230A4 penetrate the package layer 220 and allow an ambient medium to flow therethrough.

As shown in FIG. 5(b), the penetrating portions 230B1, 230B2, 230B3, 230B4 of the package structure 200B/200C surround the semiconductor device 210. As shown in FIG. 6, the penetrating portions 230B1, 230B2 penetrate the package layer 220 and respectively have a first opening 250A located at the first surface S4 and a second opening 250B located on the second surface S5. Similarly, the penetrating portions 230B3, 230B4 also penetrate the package layer 220 and respectively have a first opening 250A located at the first surface S4 and a second opening 250B located on the second surface S4. The penetrating portion 230B1, 230B2, 230B3, 230B4 allows an ambient medium to flow through the package layer 220 via the first openings 250A and the second openings 250B. In some embodiments, as shown in FIG. 5(c), the package structure 200C further includes a concave-convex structure 240 located on the third surface S6 of the package layer 220, and the ambient medium can flow through the concave-convex structure 240.

As shown in FIG. 6, the package structure 200B further includes a wiring layer 203 coupled to the semiconductor device 210 and the bearing substrate 201. In some embodiments, the wiring layer 203 includes a redistribution layer (RDL). The penetrating portions 230B1, 230B2, 230B3, 230B4 and the wiring layer 203 are not overlapped with each other in the vertical projection. In some embodiments, the package structures 200A, 200C also include a wiring layer 203. The penetrating portions 230A1, 230A2, 230A3, 230A4 of the package structure 200A and the wiring layer 203 are not overlapped with each other in the vertical projection. The penetrating portions 230B1, 230B2, 230B3, 230B4 of the package structure 200C and the wiring layer 203 are not overlapped with each other in the vertical projection.

In some embodiments, the semiconductor structure 100 shown in FIG. 1A and FIG. 1B may be replaced with any one of the package structures 200A, 200B, 200C, and the package structures 200A, 200B, 200C may be transferred to a target substrate (e.g., the transfer carriers 101B2, 101B3, 101B4) by performing the transfer steps S103, S105, S107 shown in FIG. 1A.

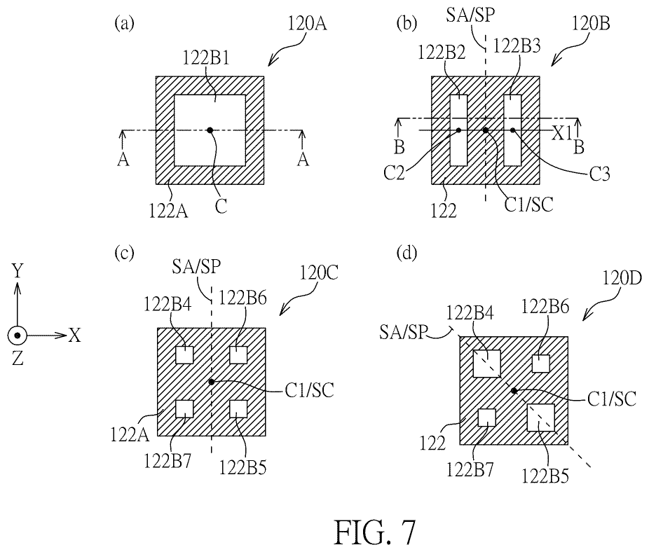

FIG. 7 shows a schematic top view of alignment keys 120A, 120B, 120C, 120D according to some embodiments of the present disclosure. In some embodiments, the alignment key 120 shown in FIG. 1B may be any one of alignment keys 120A, 120B, 120C, 120D, or a combination thereof. As shown in FIG. 7(a), the alignment key 120A includes a semiconductor portion 122A and a penetrating portion 122B1. The semiconductor portion 122A is an epitaxial stack and may include III-V compound semiconductor layers. In some embodiments, the semiconductor portion 122A of the alignment key 120A and the epitaxial stack of the semiconductor device 110 are the same. The penetrating portion 122B1 penetrates the semiconductor portion 122A. A center point (or a symmetry center) C of the alignment key 120A is located within the penetrating portion 122B1. In the alignment key 120A, the number of the penetrating portion 122B1 is one. In a top view, the penetrating portion 122B1 may be circular or a polygon, such as a square or a hexagon (not shown). The semiconductor portion 122A may be continuous and surround the penetrating portion 122B1. In the top view, the semiconductor portion 122A may be a square ring or a circle ring.

As shown in FIG. 7(b), the alignment key 120B includes a penetrating portions 122B2, 122B3 penetrating the semiconductor portion 122A. In some embodiments, the first penetrating portions 122B2, 122B3 are symmetric with respect to a symmetry center SC, a symmetry axis SA, and/or a symmetry plane SP (e.g., rotational symmetry or mirror symmetry). The symmetry axis SA and/or the symmetry plane SP pass through upper-and-lower surfaces of the alignment key 120B. In some embodiments, a center point (i.e., centroid) C1 of the alignment key 120B, a center point C2 of the first penetrating portion 122A, and a center point C3 of the penetrating portion 122B3 lie on a same axis X1, and a midpoint of a line segment connecting the center point C2 and the center point C3 overlaps the centroid C1 of the alignment key 120B. In some embodiments, the center point C1 of the alignment key 120B is overlapped with a symmetry center SC between the penetrating portion 122B2 and the penetrating portion 122B2. In some embodiments, in the top view, the penetrating portion 122B2 and the penetrating portion 122B2 have the same projected areas, and the semiconductor portion 122A is continuous and surrounds the penetrating portion 122B2 and the penetrating portion 122B2.

As shown in FIG. 7(c), the alignment key 120C includes penetrating portions 122B4-122B7 penetrate the semiconductor portion 122A. In a top view, the penetrating portions 122B4-122B7 are symmetrically arranged with a center point C1 of the alignment key 120C. In other words, the penetrating portions 122B4-122B7 are symmetric with respect to a symmetry center SC, a symmetry axis SA, and/or a symmetry plane SP (e.g., rotational symmetry or mirror symmetry). In some embodiments, in the top view, the symmetry center SC is overlapped with the center point C1 of the alignment key 120C, the symmetry axis SA and/or the symmetry plane SP passing through upper-and-lower surfaces of the alignment key 120C or left-and-right side edges of the alignment key 120C (not shown). In some embodiments, in the top view, the penetrating portions 122B4-122B7 have the same projected areas, and the semiconductor portion 122A is continuous and surround the penetrating portions 122B4-122B7. In some embodiments, in the top view, the penetrating portions 122B4-122B7 have square contours, and the semiconductor portion 122A has a square contour.

As shown in FIG. 7(d), both the penetrating portion 122B4 and the penetrating portion 122B5 have a first projected area, both the penetrating portion 122B6 and the penetrating portion 122B7 have a second projected area. In some embodiments, the first projected area and the second projected area are different. The penetrating portion 122B4-122B7 are symmetric with respect to a symmetry center SC, a symmetry axis SA, and/or a symmetry plane SP. In this embodiment, the symmetry axis SA and/or the symmetry plane SP pass through two diagonal corners of the alignment key 120D, the penetrating portion 122B4 and the penetrating portion 122B5. In other embodiments, the symmetry axis SA and/or the symmetry plane SP pass through the other two diagonal corners (not shown) of the alignment key 120D, the penetrating portion 122B6, and the penetrating portion 122B7. Other features of the alignment key 120D may refer to the description of the alignment key 120C.

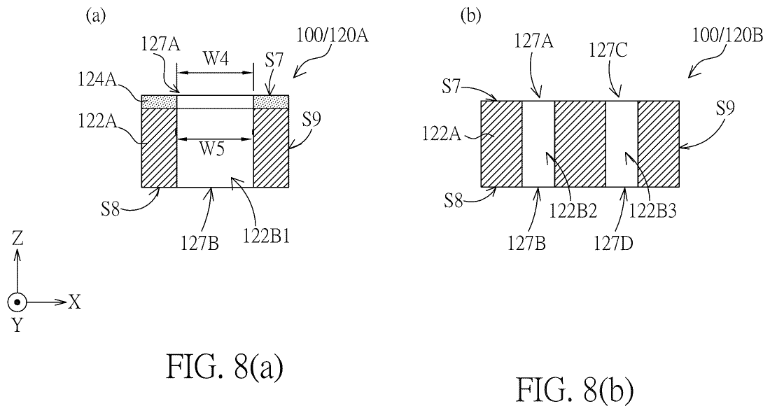

FIG. 8(a) shows a schematic cross-sectional view taken along line A-A in FIG. 7(a), and FIG. 8(b) shows a schematic cross-sectional view taken along line B-B in FIG. 7(b). In some embodiments, the alignment key 120A further includes a metal portion 124A located on one side of the semiconductor portion 122A. The alignment key 120A includes a first surface S7, a second surface S8, and a third surface S9. The second surface S8 is opposite to the first surface S7, and the third surface S9 is located between the first surface S7 and the second surface S8. The first surface S7 includes an upper surface of the metal portion 124A, the second surface S8 includes a lower surface of the semiconductor portion 122A, and the third surface S9 includes a side surface of the semiconductor portion 122A. The penetrating portion 122B1 of the alignment key 120A penetrates the semiconductor portion 122A and the metal portion 124A. The penetrating portion 122B1 has a first opening 127A located at the first surface S7 and a second opening 127B located at the second surface S8. The penetrating portion 122B1 allows an ambient medium to flow through the alignment key 120A via the first opening 127A and the second opening 127B. In some embodiments, a width W4 of the penetrating portion 122B1 in the metal portion 124A is same as its width W5 in the semiconductor portion 122A. In other embodiments, the width W4 of the penetrating portion 122B1 in the metal portion 124 is greater the width W5 in the semiconductor portion 122.

As shown in FIG. 8(b), the alignment key 120B includes a first surface S7′, a second surface S8′, and a third surface S9′. The second surface S2 is opposite to the first surface S1, and the third surface S3 may be a side surface of the semiconductor portion 122A. The penetrating portion 122B2 of the alignment key 120B has a first opening 127A located at the first surface S1 and a second opening 127B located at the second surface S2, and the penetrating portion 122B2 has a third opening 127C located at the first surface S1 and a fourth opening 127D located at the second surface S2. The penetrating portion 122B2 allows an ambient medium to flow through the alignment key 120B via the first opening 127A and the second opening 127B, and the penetrating portion 122B3 allows the ambient medium to flow through the alignment key 120B via the third opening 127C and the fourth opening 127D. In this embodiment, the alignment key 120B does not have the metal potion.

Schematic cross-sectional views of other alignment keys 120C, 120D may be referred to FIG. 8. The penetrating portions 122B4-122B7 has the same function as the penetrating portion 122B1.

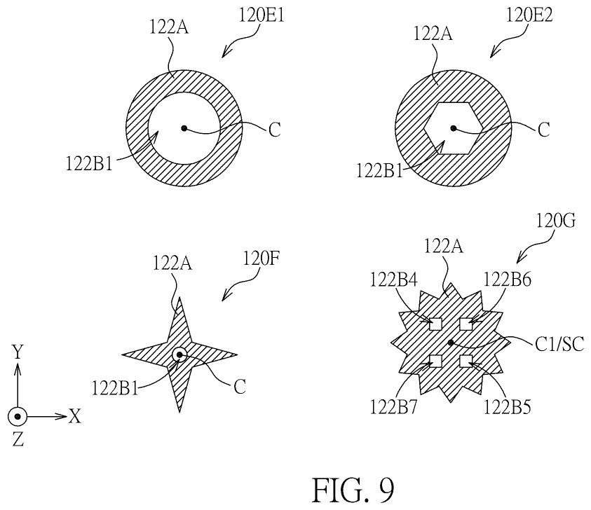

FIG. 9 shows a schematic top view of a semiconductor structure 100 according to some embodiments of the present disclosure. The semiconductor structure 100 includes alignment keys 120E1, 120E2, 120F, or 120G, and the plurality of alignment keys 120 shown in FIG. 1B may be implemented as any of the alignment keys 120E1, 120E2, 120F, 120G, or a combination thereof. The alignment keys 120E1, 120E2, 120F include a single penetrating portion 122B1 penetrating the semiconductor portion 122A. In a top view, a center point (or symmetry centers) C of the alignment keys 120E1, 120E2, 120F are located within the penetrating portion 122B1. In the top view, a contour of the penetrating portion 122B1 may be circular or a symmetric polygon, such as a hexagon or an octagon (not shown). In the top view, the semiconductor portion 122A is continuous and surrounds the penetrating portion 122B1, and a contour of the semiconductor portion 122 may be circular, a four-pointed star shape, or another symmetric pattern.

As shown in FIG. 9, the alignment key 120G includes the penetrating portions 122B4-122B7-1 penetrating the semiconductor portion 122A. In a top view, the penetrating portions 122B4-122B7 are symmetrically arranged with respect to a center point C1 of the alignment key 120F. The penetrating portions 122B4-122B7 are symmetric with respect to a symmetry center SC (e.g., rotational symmetry or mirror symmetry), and the symmetry center SC is overlapped with the center point C1 of the alignment key 120F. In the alignment key 120F, a contour of each penetrating portion 122B4-122B7 may be a square or circular. In the top view, the semiconductor portion 122A is continuous and surrounds each penetrating portion 122B4-122B7, and a contour of the semiconductor portion 122A may be a symmetric pattern with serrated edges.

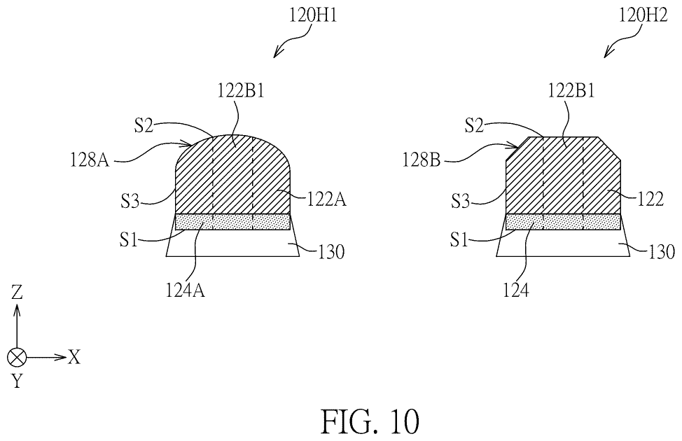

FIG. 10 shows a schematic sectional view of semiconductor structures according to some embodiments of the present disclosure. The semiconductor structure includes alignment keys 120H1 or 120H2, and the plurality of alignment keys 120 shown in FIG. 1B may be implemented as any of the alignment keys 120H1, 120H2, or a combination thereof. As shown in FIG. 10, the semiconductor portion 122A of the alignment key 120H1 has an arcuate surface 128A, and the semiconductor portion 122A of the alignment key 120H2 has a sloped surface 128B. In some embodiments, the arcuate surface 128A or the sloped surface 128B can reduce the resistance force generated by the surface (first surface S7 or second surface S8) of the semiconductor structure when the semiconductor structure is dropping. The alignment keys 120H1, 120H2 further include a metal portion 124A. The metal portion 124A and the arcuate surface 128A are located on opposite sides of the semiconductor portion 122A, and the metal portion 124A and the sloped surface 128B are located on opposite sides of the semiconductor portion 122. A single penetrating portion 122B1 or a plurality of penetrating portions penetrate the semiconductor portion 122A and the metal portion 124A. Referring to FIG. 1A and FIG. 10, in some embodiments, the metal portion 124A of the alignment keys 120H1, 120H2 contacts the adhesive layer 130 after the transfer step S101.

In conclusion, the semiconductor structures and the package structures of the present disclosure have penetrating portions to allow the ambient medium to flow therethrough. Therefore, when the semiconductor structures and the package structures are dropping, the resistance force can be reduced and the flow-velocity differential can be decreased, thereby improving the transfer accuracy of the semiconductor structures and the package structures.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

What is claimed is:

1. A semiconductor structure, comprising:
a first surface;
a second surface opposite to the first surface;
a semiconductor portion; and
a first penetrating portion penetrating the semiconductor portion, wherein the penetrating portion is communicated with an ambient medium.

2. The semiconductor structure according to claim 1, wherein, in a top view, a center point of the semiconductor structure is located within the first penetrating portion.

3. The semiconductor structure according to claim 1, further comprising:
a metal portion disposed on the semiconductor portion, wherein the first penetrating portion does not penetrate the metal portion.

4. The semiconductor structure according to claim 3, wherein the first surface includes an upper surface of the metal portion, the second surface includes a lower surface of the semiconductor portion.

5. The semiconductor structure according to claim 4, further comprising:
a third surface located between the first surface and the second surface, wherein the third surface includes a side surface of the semiconductor portion.

6. The semiconductor structure according to claim 5, further comprising:
a concave-convex structure located on the third surface.

7. The semiconductor structure according to claim 1, further comprising:
a second penetrating portion penetrating the semiconductor portion, wherein the second penetrating portion is communicated with the ambient medium.

8. The semiconductor structure according to claim 7, wherein, in a top view, the first penetrating portion has a first point, the second penetrating portion has a second point, the semiconductor portion has a third point, and a midpoint of a line segment connecting the first point and the second point overlaps the third point.

9. The semiconductor structure according to claim 7, wherein, in a top view, the first penetrating portion and the second penetrating portion have the same areas.

10. The semiconductor structure according to claim 7, wherein, in a top view, the first penetrating portion has a first contour, the second penetrating portion has a second contour, and the first contour and the second contour are symmetric patterns.

11. The semiconductor structure according to claim 1, further comprising:
a metal portion disposed on the semiconductor portion, wherein the first penetrating portion penetrates the metal portion and the semiconductor portion.

12. The semiconductor structure according to claim 1, wherein, in a top view, a contour of the first penetrating portion is a symmetric pattern.

13. The semiconductor structure according to claim 1, wherein, in a top view, a contour of the semiconductor portion is a symmetric pattern.

14. The semiconductor structure according to claim 1, wherein the semiconductor portion comprises an n-type semiconductor layer, an active layer and a p-type semiconductor layer.

15. A package structure, comprising:
a bearing substrate;
a semiconductor device disposed on the bearing substrate;
a package layer covering the semiconductor device and the bearing substrate; and
a penetrating portion penetrating the package layer and communicated with an ambient medium.

16. The package structure according to claim 15, wherein the penetrating portion and the semiconductor device are not overlapped with each other in a vertical projection.

17. The package structure according to claim 15, further comprising:
a wiring layer coupled to the semiconductor device and the bearing substrate.

18. The package structure according to claim 17, wherein the penetrating portion and the wiring layer are not overlapped with each other in the vertical projection.

19. The package structure according to claim 15, further comprising a plurality of semiconductor devices emitting different light.

20. The package structure according to claim 15, wherein the penetrating portion extends from an edge side of the semiconductor device to an edge of the package layer.
